(19) United States
(12) Patent Application Publication
(10) Pub. No.: US 2024/0339463 A1
(43) Pub. Date: Oct. 10, 2024

(54) ELECTRONIC DEVICE

(71) Applicant: Innolux Corporation, Miaoli County (TW)

(72) Inventors: Yi-Shiuan Cherng, Miaoli County (TW); Chia-Hao Tsai, Miaoli County (TW)

(73) Assignee: Innolux Corporation, Miaoli County (TW)

(21) Appl. No.: 18/597,942

(22) Filed: Mar. 7, 2024

(30) Foreign Application Priority Data
Apr. 7, 2023 (CN) 202310367662.1

(51) Int. Cl. H01L 27/12

(52) U.S. Cl. CPC H01L 27/1244

(57) ABSTRACT

An electronic device, having a peripheral area and including a first data line, a second data line, a first transistor, a second transistor, a first signal line, and a second signal line, is provided. The first data line and the second data line extend along a first direction. The first transistor and the second transistor are adjacently disposed in the peripheral area. The first transistor and the second transistor are respectively electrically connected to the first data line and the second data line. The first signal line and the second signal line extend along the first direction and are at least partially disposed between the first transistor and the second transistor. The first signal line and the second signal line are different layers.

### CROSS-REFERENCE TO RELATED APPLICATION

This application claims the priority benefit of China application serial no. 202310367662.1, filed on Apr. 7, 2023. The entirety of the above-mentioned patent application is hereby incorporated by reference herein and made a part of this specification.

### BACKGROUND

### Technical Field

The disclosure relates to an electronic device.

### Description of Related Art

The panel-type electronic device, such as the display panel and the touch display panel, is constantly improving toward high resolution. Increasing the resolution means that more electronic elements and signal circuits must be installed under the same area. The dense configuration of the signal circuits increases the load of the signal circuits, which may affect the performance of the electronic elements and reduce the quality.

### SUMMARY

The disclosure provides an electronic device, which can reduce the load of dense signal circuits.

According to an embodiment of the disclosure, an electronic device has a peripheral area and includes a first data line, a second data line, a first transistor, a second transistor, a first signal line, and a second signal line. The first data line and the second data line extend along a first direction. The first transistor and the second transistor are disposed in the peripheral area and are adjacent to each other. The first transistor and the second transistor are respectively electrically connected to the first data line and the second data line. The first signal line and the second signal line extend along the first direction and are at least partially disposed between the first transistor and the second transistor. The first signal line and the second signal line are different layers.

According to an embodiment of the disclosure, an electronic device has a peripheral area and includes a first data line, a second data line, a first transistor, a second transistor, a signal line, and a connection portion. The first data line and the second data line extend along a first direction. The first transistor and the second transistor are disposed in the peripheral area and are respectively electrically connected to the first data line and the second data line. The signal line is disposed in the peripheral area and extends along a second direction. The first direction is different from the second direction. The connection portion is connected to the signal line. The connection portion includes a first branch and a second branch. The first branch electrically connects the first transistor and the signal line, and the second branch electrically connects the second transistor and the signal line.

According to an embodiment of the disclosure, an electronic device has a peripheral area and includes multiple data lines and a driving circuit. The data lines extend along a first direction. The driving circuit is disposed in the peripheral area and includes multiple transistors, a first signal line, and a second signal line. The transistors are electrically connected to the data lines. Each of the transistors includes a gate. The first signal line extends along a second direction. The first direction is different from the second direction. The first signal line is electrically connected to the gate of at least one of the transistors. The second signal line is adjacent to the first signal line and extends along the second direction. The second signal line is electrically connected to the gate of at least another one of the transistors. At least part of the transistors are disposed between the first signal line and the second signal line.

### BRIEF DESCRIPTION OF THE DRAWINGS

FIG. 1 is a schematic top view of an electronic device according to an embodiment of the disclosure.

FIG. 2 is a schematic cross-sectional view of a pixel structure in an electronic device according to an embodiment of the disclosure.

FIG. 3A and FIG. 3B are schematic views of a driving circuit of an electronic device according to an embodiment of the disclosure.

FIG. 4 is a schematic cross-sectional view of a line I-I in FIG. 3B.

FIG. 5A and FIG. 5B are schematic views of a driving circuit of an electronic device according to an embodiment of the disclosure.

FIG. 6 is a schematic cross-sectional view of a line II-II in FIG. 5B.

FIG. 7 is a schematic view of a driving circuit of an electronic device according to an embodiment of the disclosure.

FIG. 8 is a schematic view of a driving circuit of an electronic device according to an embodiment of the disclosure.

FIG. 9 is a schematic view of a driving circuit of an electronic device according to an embodiment of the disclosure.

### DETAILED DESCRIPTION OF DISCLOSED EMBODIMENTS

Reference will now be made in detail to the exemplary embodiments of the disclosure, examples of which are illustrated in the drawings. Wherever possible, the same reference numerals are used in the drawings and the description to refer to the same or similar parts.

The disclosure can be understood by referring to the following detailed description in conjunction with the drawings. It should be noted that in order to facilitate the understanding of the reader and the simplicity of the drawings, multiple drawings in the disclosure only depict a part of an electronic device, and specific elements in the drawings are not drawn according to actual scale. In addition, the number and the size of each element in the drawings are for illustration only and are not intended to limit the scope of the disclosure.

Throughout the specification and the appended claims of the disclosure, certain terms are used to refer to specific elements. It should be understood by persons skilled in the art that electronic device manufacturers may refer to the same element by different names. The disclosure does not intend to distinguish between elements with the same function but different names. In the following specification and claims, words such as “including”, “containing”, and “having” are open-ended words, so the words should be interpreted as “comprising but not limited to . . . ”. Therefore, when the terms “including”, “containing”, and/or “having” are used in the description of the disclosure, the words designate the presence of a corresponding feature, region, step, operation, and/or component, but do not exclude the presence of one or more corresponding features, regions, steps, operations, and/or components.

Directional terms, such as “upper”, “lower”, “front”, “rear”, “left”, and “right”, mentioned in the disclosure are only directions with reference to the drawings. Therefore, the used directional terms are used to illustrate, but not to limit, the disclosure. In the drawings, each drawing illustrates the general characteristics of a method, a structure, and/or a material used in a specific embodiment. However, the drawings should not be construed to define or limit the scope or the nature covered by the embodiments. For example, the relative sizes, thicknesses, and positions of various film layers, regions, and/or structures may be reduced or enlarged for clarity.

When a corresponding component (for example, a film layer or a region) is referred to as being “disposed or formed on another component”, the component may be directly disposed or formed on the other component, or there may be another component between the two. On the other hand, when a component is referred to as being “directly disposed or formed on another component”, there is no component between the two. In addition, when a component is referred to as being “disposed or formed on another component”, the two have an upper-lower relationship in the top view direction. The component may be above or below the other component, and the upper-lower relationship depends on the orientation of the device.

It should be understood that when a component or a film layer is referred to as being “connected to” another component or film layer, the component may be directly connected to the other component or film layer, or there may be a component or a film layer inserted between the two. When a component is referred to as being “directly connected” to another component or film layer, there is no component or film layer inserted between the two. Also, when a component is referred to as being “coupled to another component (or a variation thereof)”, the component may be directly connected to the other component or indirectly connected (such as electrically connected) to the other component through one or more components.

The terms “about”, “equal to”, “equivalent” or “same”, “essentially”, or “substantially” are generally interpreted as within 20% of a given value or range, or as within 10%, 5%, 3%, 2%, 1%, or 0.5% of the given value or range.

Ordinal numbers, such as “first” and “second”, used in the specification and the claims are used to modify elements, and the terms do not imply and represent that the element(s) have any previous ordinal numbers, nor do they represent the order of a certain element and another element or the order of a manufacturing method. The use of the ordinal numbers is only used to clearly distinguish between an element with a certain name and another element with the same name. The claims and the specification may not use the same terms, whereby a first component in the specification may be a second component in the claims.

In the disclosure, the electronic device may include a display device, a backlight device, an antenna device, a sensing device, or a splicing device, but not limited thereto. The electronic device may be a bendable or flexible electronic device. The electronic device may include, for example, liquid crystal, a light emitting diode, fluorescence, phosphor, other suitable display media, or a combination of the above. The display device may be a non-self-luminous display device or a self-luminous display device. The antenna device may be a liquid crystal type antenna device or a non-liquid crystal type antenna device. The sensing device may be a sensing device for sensing capacitance, light, heat, or ultrasound, but not limited thereto. The splicing device may be, for example, a display splicing device or an antenna splicing device, but not limited thereto. It should be noted that the electronic device may be any permutation and combination of the above, but not limited thereto. In addition, the appearance of the electronic device may be rectangular, circular, polygonal, a shape with curved edges, or other suitable shapes. The electronic device may have a peripheral system, such as a driving system, a control system, and a light source system, to support the display device, the antenna device, a wearable device (such as including augmented reality or virtual reality), a vehicle-mounted device (such as including a car windshield), or the splicing device. Hereinafter, a panel-type device will be used as the electronic device to illustrate the content of the disclosure, but the disclosure is not limited thereto.

In the drawings of the disclosure, the X-axis, the Y-axis, and the Z-axis are marked to represent the orientation of individual structures. In some embodiments, the X-axis, the Y-axis, and the Z-axis represent axial directions that intersect in pairs, and an angle between the two axial directions may be 90 degrees or other angles.

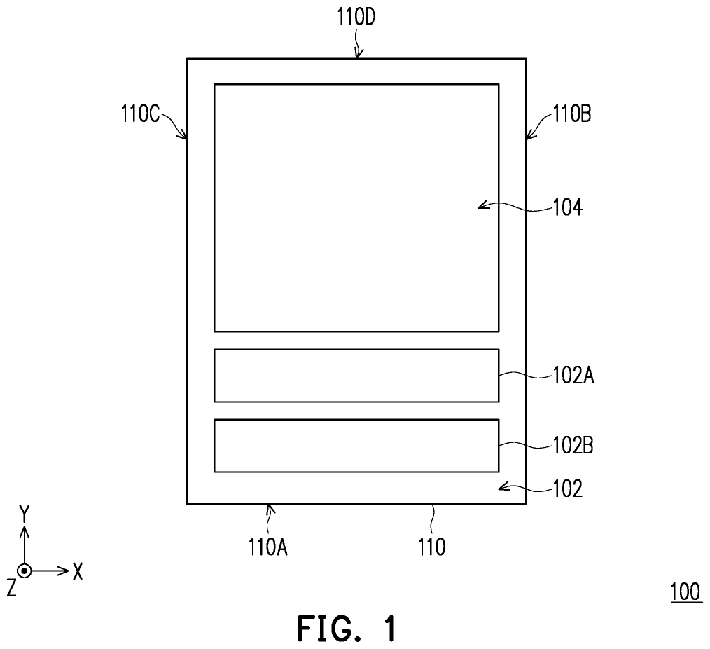

FIG. 1 is a schematic top view of an electronic device according to an embodiment of the disclosure. FIG. 1 substantially shows the regional layout of an electronic device 100, and multiple electronic elements and multiple signal lines may be disposed in a single region. The electronic element may include a sensing element, a passive element, and an active element, such as a sensor, a capacitor, a resistor, an inductor, a diode, and a transistor. The diodes may include a light emitting diode or a photodiode. The light emitting diode may, for example, include an organic light emitting diode (OLED), a mini LED, a micro LED, or a quantum dot LED, but not limited thereto. The signal line may connect the electronic elements according to requirements to implement the required signal transmission and electrical connection. In order to clearly illustrate the features of the electronic device 100, the disclosure may omit the description and the drawings of some electronic elements and signal lines. However, persons skilled in the art should understand that the omitted electronic elements are also disposed in the electronic device 100 for implementing the functions of the electronic device 100.

As shown in FIG. 1, the electronic device 100 may have a peripheral area 102 and a display area 104. The display area 104 is adjacent to the peripheral area 102, and the display area 104 may be substantially surrounded by the peripheral area 102. In some embodiments, the electronic device 100 may include multiple elements, such as pixel structures (not shown), in the display area 104 for displaying an image. In addition, the electronic device 100 may also include a sensing element, a light emitting element, etc. in the display area 104 to implement functions such as sensing and light emission. The electronic device 100 mainly implements the required functions, such as displaying an image, light emission, touch sensing, temperature sensing, and light sensing, by the electronic elements disposed in the display area 104. The peripheral area 102 is a region surrounding the display area 104. The electronic device 100 may be provided with a driving circuit, a test circuit, etc. in the peripheral area 102. The electronic device 100 may further include a driving circuit area 102A, a test circuit area 102B, etc. in the peripheral area 102, wherein the electronic elements in the driving circuit area 102A and the test circuit area 102B are not directly used to implement functions such as displaying an image, light emission, touch sensing, temperature sensing, and light sensing, but are used to test or drive the electronic elements, such as display pixels and the sensing element, in the display area 104.

In FIG. 1, the display device 100 has a panel type, which at least includes a substrate 110. In some embodiments, the peripheral area 102 of the electronic device 100 may be at least provided with the driving circuit area 102A, and the driving circuit area 102A may be disposed on the substrate 110. The peripheral area 102 of the electronic device 100 may further include the test circuit area 102B. The substrate 110 includes a side 110A, a side 110B, a side 110C, and a side 110D, wherein the side 110A is opposite to the side 110D, and the side 110B is opposite to the side 110C. In some embodiments, the driving circuit area 102A and the test circuit area 102B are both located between the display area 104 and the side 110A of the substrate 110, so the display area 104 of the display device 100 may extend between the side 110B and the side 110C of the substrate 110 as much as possible to implement a narrow frame design. In some embodiments, based on the narrow frame design, the display device 100 may be applied to a splicing device. In some embodiments, the substrate 110 further includes a side 110D, and the display area 104 may also extend toward the side 110D of the substrate 110 as much as possible to implement the narrow frame design, but the disclosure is not limited thereto.

In some embodiments, the driving circuit area 102A is disposed between the display area 104 and the test circuit area 102B, but not limited thereto. In some embodiments, the test circuit area 102B may be disposed between the display area 104 and the driving circuit area 102A or a part of the test circuit area 102B may be disposed between the display area 104 and the driving circuit area 102A, and another part may be disposed between the driving circuit area 102A and the side 110A of the substrate 110. The driving circuit area 102A may include at least one transistor and may be used to provide a driving signal to the electronic elements, such as the display pixels and the sensing element, in the display area 104. In some embodiments, the driving circuit area 102A may further include an integrated circuit, and the integrated circuit is electrically connected to multiple transistors disposed in the driving circuit area 102A. In some embodiments, the test circuit area 102B may include a transistor, and one of a source and a drain of the transistor in the test circuit area 102B is connected to a test signal. The test circuit area 102B may be used to provide the test signal to the electronic elements in the display area 104 to test whether the electronic elements in the display area 104 are normal. In some embodiments, the test circuit area 102B may only run in a test program but not in actual use. In other words, when the user is using the electronic device 100, such as watching an image and performing a touch operation, a test circuit in the test circuit area 102B may not run and be an idle element, but not limited thereto. In addition, the test signal connected to one of the source and the drain of the transistor in the test circuit area 102B may be provided by other signal sources instead of the integrated circuit of the driving circuit area 102A.

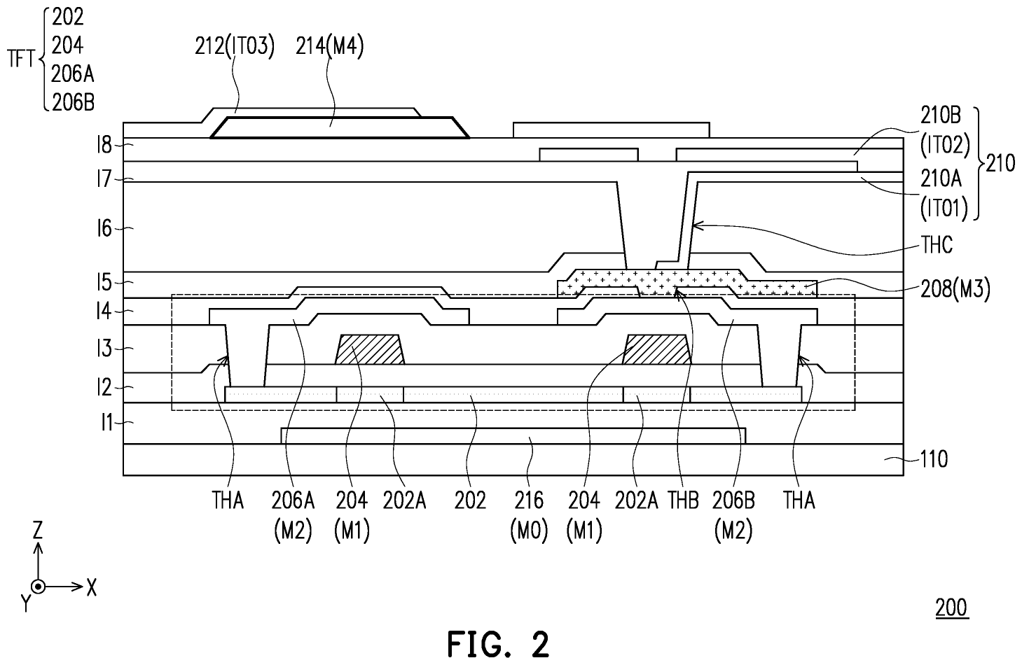

FIG. 2 is a schematic cross-sectional view of a pixel structure in an electronic device according to an embodiment of the disclosure. In FIG. 2, a pixel structure 200 is, for example, an element disposed in the display area 104 of the display device 100 of FIG. 1. The pixel structure 200 is disposed on the substrate 110 and includes a semiconductor layer 202, a gate 204, a source 206A, a drain 206B, a connection electrode 208, a pixel electrode 210, a common electrode 212, a common electrode line 214, and a light shielding layer 216. In addition, the pixel structure 200 also includes multiple layers of insulation layers I1 to I8 to separate individual conductive layers. The light shielding layer 216 is disposed on the substrate 110 and is located between the semiconductor layer 202 and the substrate 110 for shielding light entering the semiconductor layer 202 from the substrate 110. The insulation layer I1 is disposed between the light shielding layer 216 and the semiconductor layer 202. The gate 204 overlaps with the semiconductor layer 202 in the Z-axis direction to define a channel area 202A. The insulation layer 12 is disposed on the gate 204 and the semiconductor layer 202, and may be understood as a gate insulation layer. FIG. 2 is illustrated by taking the gate 204 overlapping with two parts of the same semiconductor layer 202 to define two channel areas 202A as an example, but in other embodiments, the gate 204 may only overlap with a single part of the semiconductor layer 202. The insulation layer 13 is disposed on the gate 204 to cover the gate 204, and the source 206A and the drain 206B are disposed on the insulation layer 13, wherein the source 206A and the drain 206B may be respectively connected to the semiconductor layer 202 through a perforation THA penetrating the insulation layer 12 and the insulation layer 13. The insulation layer 14 covers the source 206A and the drain 206B, and the connection electrode 208 is disposed on the insulation layer 14. The connection electrode 208 may be connected to the drain 206B through a perforation THB penetrating the insulation layer 14. The insulation layer 15 covers the connection electrode 208, and the insulation layer 16 covers the insulation layer 15. In some embodiments, the thickness of the insulation layer 16 may be greater than the thickness of the insulation layer 15, and the insulation layer 16 may be understood as a flat layer to provide a flat plane to support a subsequently formed film layer. In the embodiment, the pixel electrode 210 may include a first electrode layer 210A and a second electrode layer 210B. The first electrode layer 210A may be disposed on the insulation layer 16 and may be connected to the connection electrode 208 through a perforation THC penetrating the insulation layer 15 and the insulation layer 16. The insulation layer 17 partially covers the first electrode layer 210A, and the second electrode layer 210B is disposed on the insulation layer 17 and contacts the first electrode layer 210A not covered by the insulation layer 17. The insulation layer 18 covers the second electrode layer 210B of the pixel electrode 210. The common electrode line 214 and the common electrode 212 are sequentially disposed on the insulation layer 18. In this way, the pixel structure 200 may include a transistor TFT composed of the semiconductor layer 202, the gate 204, the source 206A, and the drain 206B and the pixel electrode 210 composed of the first electrode layer 210A and the second electrode layer 210B, and the transistor TFT is electrically connected to the pixel electrode 210.

In the embodiment, the light shielding layer 216 is formed by patterning a conductive layer M0, the gate 204 is formed by patterning a conductive layer M1, the source 206A and the drain 206B are patterned by a conductive layer M2, the connection electrode 208 is formed by patterning a conductive layer M3, the first electrode layer 210A of the pixel electrode 210 is formed by patterning a conductive layer ITO1, the second electrode layer 210B of the pixel electrode 210 is formed by patterning a conductive layer ITO2, the common electrode line 214 is formed by patterning a conductive layer M4, and the common electrode 212 is formed by patterning the conductive layer ITO3. Therefore, when the pixel structure 200 is applied to the electronic device 100, the electronic device 100 needs eight layers of conductive layers M0 to M4 and ITO1 to ITO3 to implement the electronic elements disposed in the display area 104. At the same time, the electronic device 100 may also use the conductive layers to manufacture the driving circuit area 102A, the test circuit area 102B, etc. located in the peripheral area 102. In some embodiments, the material of the conductive layers M0 to M4 may be metal, and the material of the conductive layers ITO1 to ITO3 may be a transparent conductive material. In addition, the material of the insulation layers I1 to I8 includes an inorganic insulating material, such as silicon oxide, silicon nitride, etc., or an organic insulating material. In some embodiments, the display area 104 may also include a data line connected to the source 206A of the pixel structure 200 and a scan line connected to the gate 204 of the pixel structure 200, and a circuit structure in the driving circuit area 102A may include a multiplexer connected to the data line, a gate driving circuit connected to the scan line, or other circuit structures required to implement the functions of the pixel structure 200.

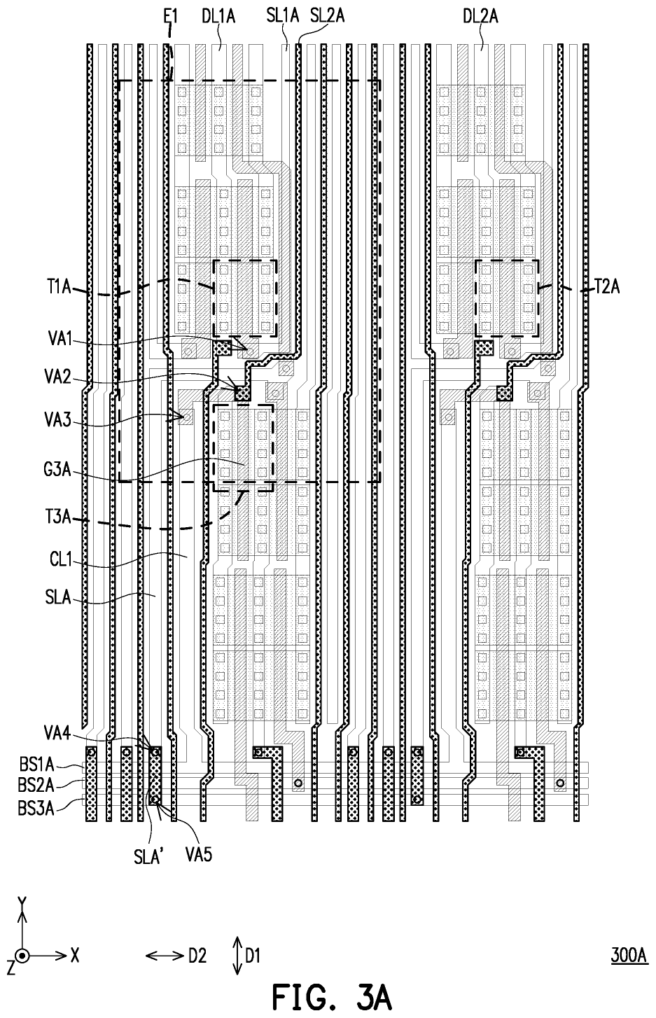

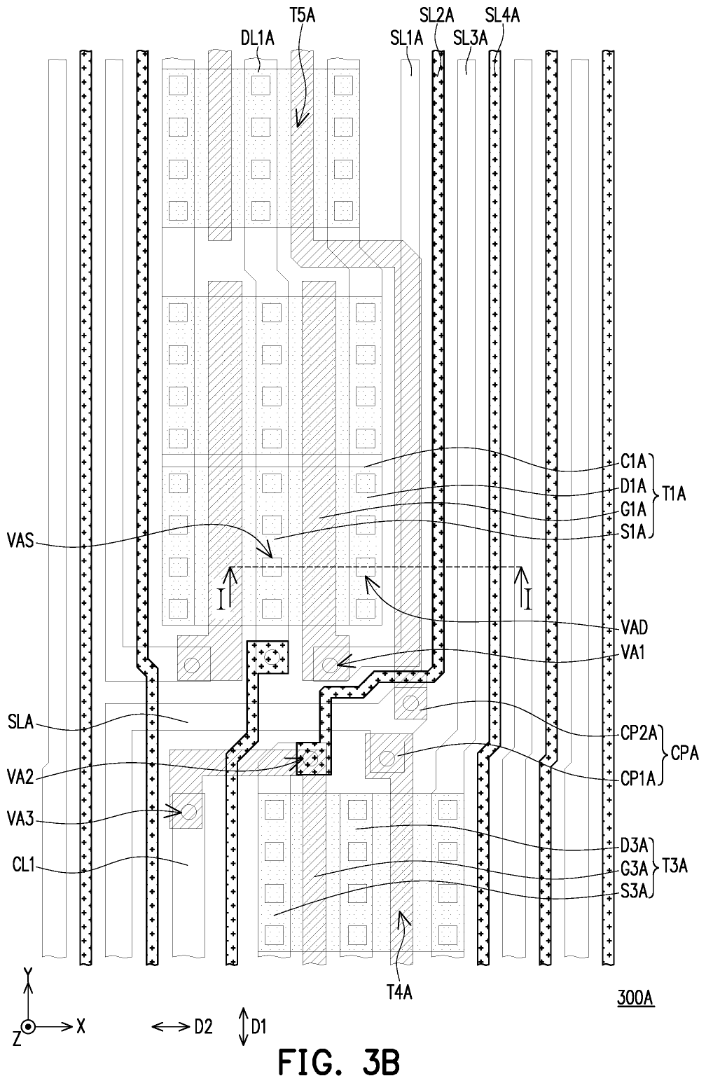

FIG. 3A and FIG. 3B are schematic views of a driving circuit of an electronic device according to an embodiment of the disclosure, wherein FIG. 3B is an enlarged view of a region E1 of FIG. 3A. A driving circuit 300A of FIG. 3A may be applied to the electronic device 100 of FIG. 1 and may be specifically used as a possible implementation of the driving circuit area 102A in the electronic device 100. Therefore, it can be understood that the driving circuit 300A of FIG. 3A is disposed on the substrate 110 of FIG. 1 and is located in the peripheral area 102. Please refer to FIG. 1, FIG. 3A, and FIG. 3B at the same time. The electronic device 100 having the driving circuit 300A includes a first data line DL1A, a second data line DL2A, a first transistor TIA, a second transistor T2A, a first signal line SL1A, and a second signal line SL2A. The first data line DL1A and the second data line DL2A extend along a first direction D1, wherein the first direction D1 is, for example, parallel to the Y-axis. The first transistor TIA and the second transistor T2A are disposed in the peripheral area 102 and are adjacently disposed. For example, the first transistor TIA and the second transistor T2A are arranged in a second direction D2 and there may be no other transistor between the first transistor TIA and the second transistor T2A, wherein the second direction D2 is, for example, parallel to the X-axis. The first transistor TIA and the second transistor T2A are respectively electrically connected to the first data line DL1A and the second data line DL2A. The first signal line SL1A and the second signal line SL2A also extend along the first direction D1, and the first signal line SL1A and the second signal line SL2A are at least partially disposed between the first transistor TIA and the second transistor T2A.

For the convenience of identification, in FIG. 3A and FIG. 3B, different patterns represent different film layers, so it can be known from FIG. 3A and FIG. 3B that the first signal line SL1A and the second signal line SL2A are different layers. Since the first signal line SL1A and the second signal line SL2A are different layers, the first signal line SL1A and the second signal line SL2A may be electrically isolated, so the contour orthographic projections of the first signal line SL1A and the second signal line SL2A on the plane of the X-axis and the Y-axis are adjacent to each other. For example, the contour orthographic projections of the first signal line SL1A and the second signal line SL2A on the plane of the X-axis and the Y-axis may be substantially aligned with each other, only separated by a small distance, or slightly overlapped. Therefore, the first signal line SL1A and the second signal line SL2A may adopt a relatively dense arrangement density configuration. In addition, the first signal line SL1A and the second signal line SL2A are different layers, so even if the first signal line SL1A and the second signal line SL2A are densely arranged on the plane of the X-axis and the Y-axis, the two can also reduce signal interference with each other due to the structure of different layers. Therefore, even if the first signal line SL1A and the second signal line SL2A are densely arranged, good signal transmission efficiency can be maintained.

In some embodiments, the first data line DL1A, the second data line DL2A, the first transistor TIA, the second transistor T2A, the first signal line SL1A, and the second signal line SL2A may be manufactured by adopting the film layers, such as the conductive layers M0 to M4 and ITO1 to ITO3, of FIG. 2. Selecting different layers of the conductive layers M0 to M4 and ITO1 to ITO3 to manufacture adjacent conductive elements (for example, signal lines, conductive patterns, etc.) helps to increase the configuration density of the conductive elements. In some embodiments, when the conductive layer M2 and the conductive layer M3 are selected to respectively form the adjacent conductive elements, the minimum distance between the adjacent conductive elements (the linear distance between the two elements may be, for example, measured along a direction inclined relative to the second direction D2) may be L23, and L23 is, for example, greater than or equal to 0.4 microns or 0.3 microns, but not limited thereto. In some embodiments, when the conductive layer M1 and the conductive layer M2 are selected to respectively form the adjacent conductive elements, the minimum distance between the adjacent conductive elements may be L12, and L12 may be 1.25 times L23 or may be, for example, greater than or equal to 0.5 microns. In some embodiments, when the conductive layer M0 and the conductive layer M2 are selected to respectively form the adjacent conductive elements, the minimum distance between the adjacent conductive elements may be L02, and L02 may be 2 times L23 or may be, for example, greater than or equal to 0.8 microns. In some embodiments, when the conductive layer M2 and the conductive layer ITO1 are selected to respectively form the adjacent conductive elements, the minimum distance between the adjacent conductive elements may be L25, and L25 may be 1.75 times L23 or may be, for example, greater than or equal to 0.7 microns. In some embodiments, when the conductive layer ITO1 and the conductive layer ITO2 are selected to respectively form the adjacent conductive elements, the minimum distance between the adjacent conductive elements may be L56, and L56 may be 7.25 times L23 or may be, for example, greater than or equal to 2.9 microns. In some embodiments, when the conductive layer M2 and the conductive layer M4 are selected to respectively form the adjacent conductive elements, the minimum distance between the adjacent conductive elements may be L24, and L24 may be 7.5 times L23 or may be, for example, greater than or equal to 3.0 microns.

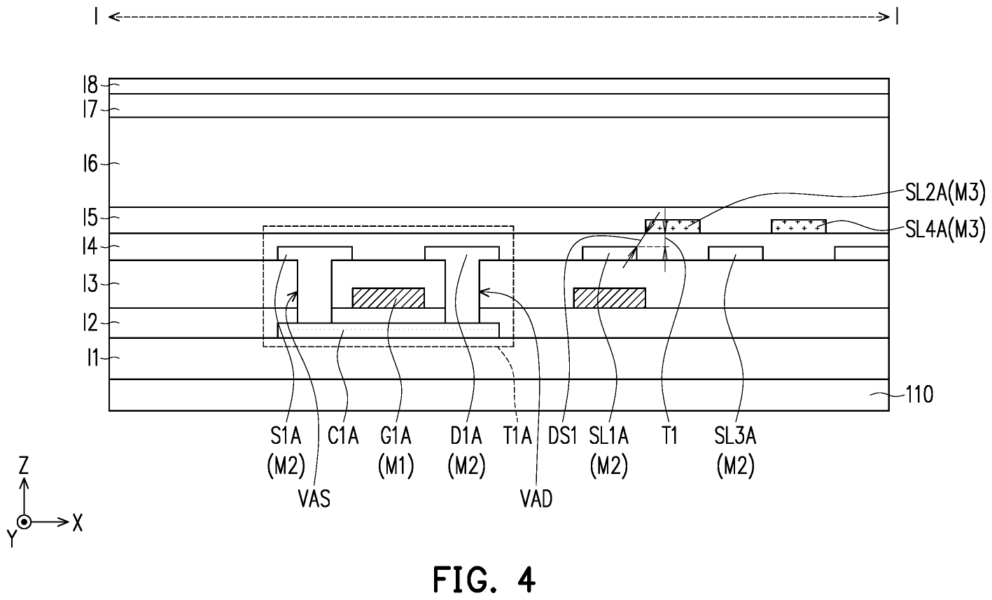

For example, FIG. 4 is a schematic cross-sectional view of a line I-I in FIG. 3B. Each layer in the cross-section of FIG. 4 corresponds to a layer of FIG. 2, so the layer marked with the same reference numeral in the two drawings represent the same layer. Referring to FIG. 3B and FIG. 4, the first transistor TIA may include a gate G1A, a source S1A, a drain D1A, and a semiconductor layer CIA, wherein the gate G1A is manufactured by the conductive layer M1 in FIG. 2, the source S1A and the drain D1A are manufactured by the conductive layer M2 in FIG. 2, and the semiconductor layer CIA is the same layer as the semiconductor layer 202 in FIG. 2. The source S1A and the drain D1A may be respectively electrically connected to the semiconductor layer 202 through a conductive via VAS and a conductive via VAD. The first signal line SL1A may be manufactured by one of the conductive layers M0 to M4 and ITO1 to ITO3 (for example, the conductive layer M2, also referred to as a first conductive layer here), and the second signal line SL2A may be manufactured by another one of the conductive layers M0 to M4 and ITO1 to ITO3 (for example, the conductive layer M3, also referred to as a second conductive layer here). In some embodiments, the first signal line SL1A and the second signal line SL2A are manufactured by adopting two different layers of the conductive layers M0 to M4 and ITO1 to ITO3, so the electronic device 100 also includes an insulation layer, and the insulation layer is disposed between the first signal line SL1A and the second signal line SL2A. For example, in FIG. 4, the first signal line SL1A and the second signal line SL2A are respectively the conductive layer M2 and the conductive layer M3, so the insulation layer 14 is disposed between the first signal line SL1A and the second signal line SL2A.

In some embodiments, two of the conductive layers M0 to M4 and ITO1 to ITO3 may be selected as the first conductive layer and the second conductive layer forming the first signal line SL1A and the second signal line SL2A. In some embodiments, a separation distance T1 between the first conductive layer and the second conductive layer in a thickness direction may be greater than or equal to 0.5 microns, wherein the thickness direction is, for example, a direction parallel to the Z-axis. In some embodiments, the minimum separation distance DS1 between the first signal line SL1A and the second signal line SL2A may be 0.4 microns. In the embodiment, although the first signal line SL1A and the second signal line SL2A are closely disposed on the plane of the X-axis and the Y-axis, the first signal line SL1A and the second signal line SL2A are spaced apart in the Z-axis direction, which helps to improve the layout density of the signal lines to achieve a high resolution design, prevents a short circuit caused by the first signal line SL1A and the second signal line SL2A being connected to each other, and helps to reduce parasitic capacitance between the first signal line SL1A and the second signal line SL2A to reduce the load of the signal lines to achieve the ideal signal transmission efficiency. In addition, in some embodiments, the electronic device 100 may further include a third signal line SL3A and a fourth signal line SL4A disposed between the first transistor TIA and the second transistor T2A in the driving circuit 300A. The first signal line SL1A, the second signal line SL2A, the third signal line SL3A, and the fourth signal line SL4A may be four signal lines closely disposed on the plane of the X-axis and the Y-axis. The third signal line SL3A may be the same layer as the first signal line SL1A, and the fourth signal line SL4A may be the same layer as the second signal line SL2A, but the disclosure is not limited thereto. For example, the first signal line SL1A, the second signal line SL2A, the third signal line SL3A, and the fourth signal line SL4A may be manufactured by respectively adopting three different layers of the conductive layers M0 to M4 and ITO1 to ITO3 in FIG. 2. In this way, any adjacent two of the first signal line SL1A, the second signal line SL2A, the third signal line SL3A, and the fourth signal line SL4A are different layers, but not limited to adjacent conductive layers.

In FIG. 3A and FIG. 3B, the electronic device 100 further includes a signal line BS1A, a signal line BS2A, a signal line BS3A, etc. The signal line BS1A, the signal line BS2A, and the signal line BS3A extend along the second direction D2, wherein the second direction D2 is substantially parallel to the X-axis direction. The first signal line SL1A is electrically connected to the gate G1A of the transistor TIA and may extend along the first direction D1 to be connected to other signal lines not shown in the drawings extending along the second direction D2, wherein the so-called other signal lines extending along the second direction D2 may be similar to the signal line BS1A, the signal line BS2A, and the signal line BS3A in FIG. 3A. In other words, the signal line BS1A, the signal line BS2A, and the signal line BS3A may be used to transfer gate signals. In FIG. 3B and FIG. 4, the first signal line SL1A is, for example, manufactured by the conductive layer M2, the gate G1A of the first transistor TIA is manufactured, for example, by the conductive layer M1, and the first signal line SL1A may be connected to the gate G1A of the first transistor TIA through a conductive via VA1 (shown in FIG. 3A and FIG. 3B).

In FIG. 3A and FIG. 3B, the electronic device 100 further includes a third transistor T3A. The third transistor T3A includes a gate G3A, a source S3A, and a drain D3C. The gate G3A is connected to a connection line CLI through a conductive via VA3, and the connection line CLI is connected to the signal line BS1A. The second signal line SL2A is electrically connected to the source S3A of the transistor T3A through the conductive via VA2. It can be seen that the first signal line SL1A is used to transmit the gate signal of the first transistor TIA and the second signal line SL2A is used to transmit the data signal of the third transistor T3A. Compared with other signals (for example, the data signals transmitted by the data lines), the gate signals are more easily affected by parasitic capacitance. However, in the embodiment, the first signal line SL1A and the second signal line SL2A are different layers, which can reduce parasitic capacitance between the two and maintain the ideal signal transmission quality. In FIG. 3A and FIG. 3B, the electronic device 100 further includes a connection portion CPA and a common signal line SLA. The connection portion CPA is electrically connected to the common signal line SLA, as shown in FIG. 3A, the common signal line SLA may be connected to a common signal line SLA′ through a conductive via VA4, and the common signal line SLA′ may be connected to the signal line BS3A through a conductive via VA5. In FIG. 3A and FIG. 3B, the connection portion CPA includes a first branch CP1A and a second branch CP2A, wherein the first branch CP1A is electrically connected to the transistor T4A and the signal line BS3A, and the second branch CP2A is electrically connected to the transistor T5A and the signal line BS3A.

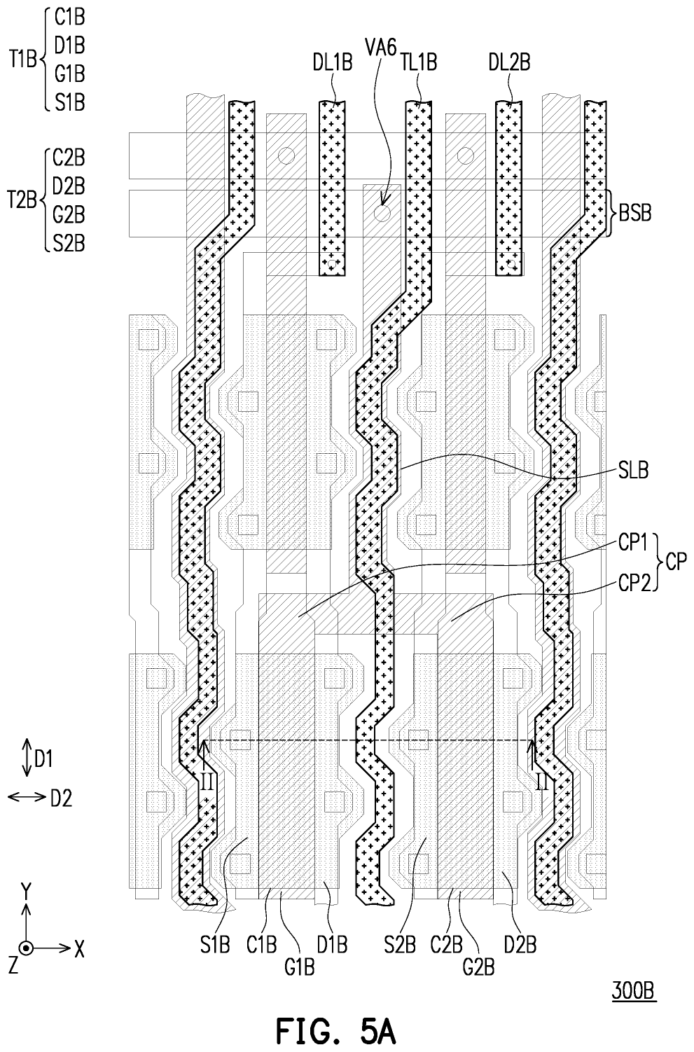

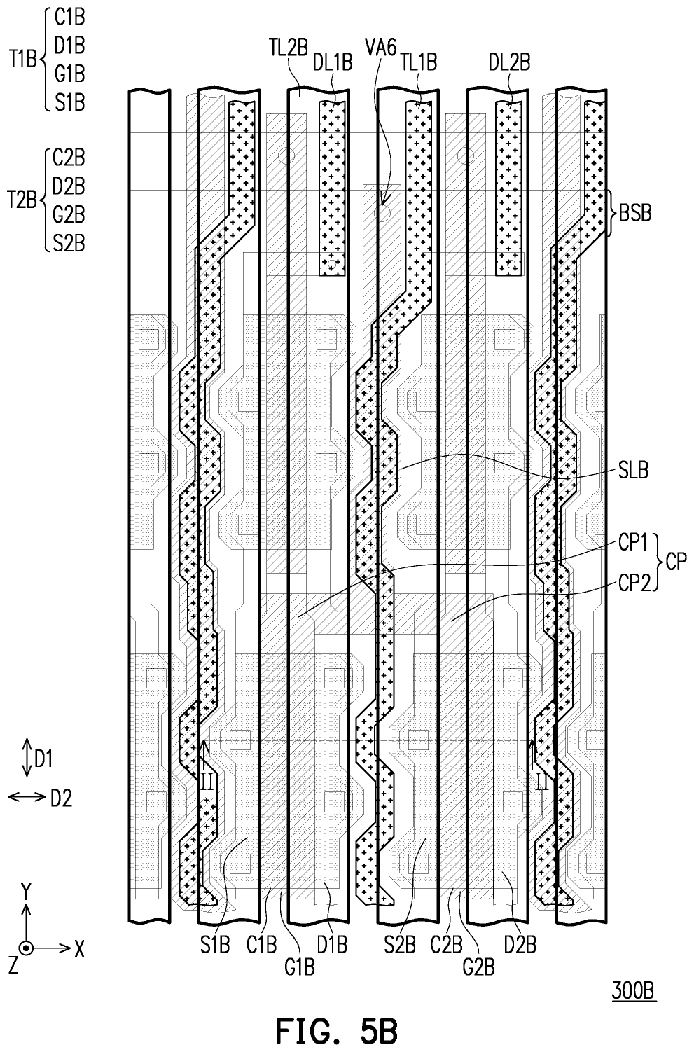

FIG. 5A and FIG. 5B are schematic views of a driving circuit of an electronic device according to an embodiment of the disclosure, wherein FIG. 5A is substantially similar to FIG. 5B, and vertical signal lines are added to FIG. 5B compared with FIG. 5A. A driving circuit 300B shown in FIG. 5A and FIG. 5B may be applied to the electronic device 100 of FIG. 1 and may be specifically used as a possible implementation of the driving circuit area 102A in the electronic device 100. Therefore, it can be understood that the driving circuit 300B of FIG. 5A and FIG. 5B is disposed on the substrate 110 of FIG. 1 and is located in the peripheral area 102. Please refer to FIG. 1, FIG. 5A, and FIG. 5B at the same time. The electronic device 100 having the driving circuit 300B includes a first data line DL1B, a second data line DL2B, a first transistor T1B, a second transistor T2B, a signal line BSB, and a connection portion CP. The first data line DL1B and the second data line DL2B extend along the first direction D1. The first transistor T1B and the second transistor T2B are disposed in the peripheral area 102 (refer to FIG. 1) and are respectively electrically connected to the first data line DL1B and the second data line DL2B. Each of the first data line DL1B and the second data line DL2B may extend along the first direction D1 to be connected to other transistors. The signal line BSB is disposed in the peripheral area 102 (refer to FIG. 1) and extends along the second direction D2. The first direction D1 is different from the second direction D2, wherein the first direction D1 is, for example, parallel to the Y-axis, and the second direction D2 is, for example, parallel to the X-axis. The connection portion CP is electrically connected to the signal line BSB. The connection portion CP includes a first branch CP1 and a second branch CP2, wherein the first branch CP1 is electrically connected to the first transistor T1B and the signal line BSB, and the second branch CP2 is electrically connected to the second transistor T2B and the signal line BSB.

Specifically, the first branch CP1 and the second branch CP2 of the connection portion CP are connected to a common signal line SLB. The common signal line SLB substantially extends along the first direction D1 toward the signal line BSB and is connected to the signal line BSB through a conductive via VA6. Therefore, the first branch CP1 and the second branch CP2 may be electrically connected to the signal line BSB. In other words, the common signal line SLB enables the first branch CP1 to be electrically connected to the first transistor TIA and the signal line BSB, and the second branch CP2 to be electrically connected to the second transistor T1B and the signal line BSB. In FIG. 5A and FIG. 5B, the first branch CP1 and the second branch CP2 are symmetrical.

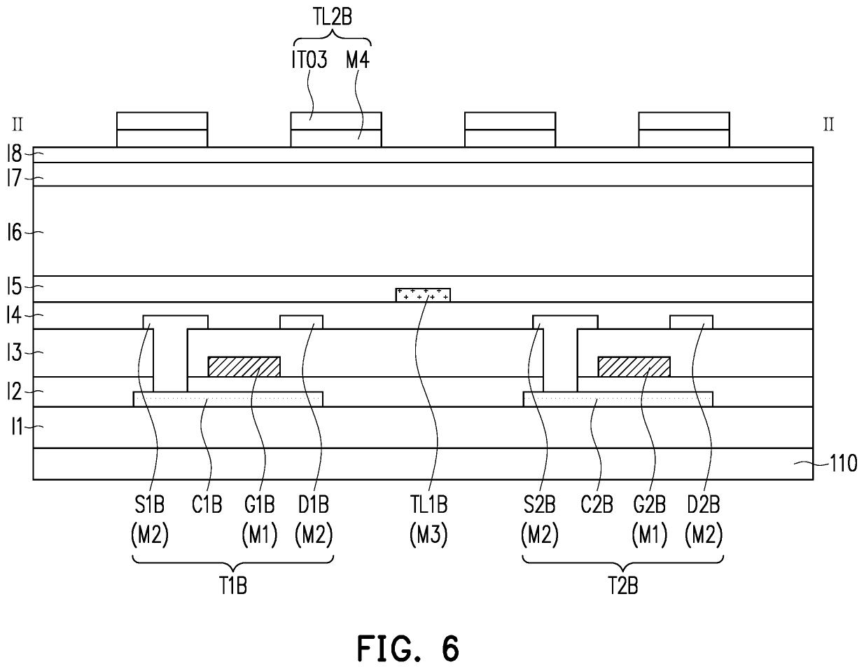

The first data line DL1B, the second data line DL2B, the first transistor T1B, the second transistor T2B, the signal line BSB, and the connection portion CP may be manufactured by adopting the film layers, such as the conductive layers M0 to M4 and ITO1 to ITO3, of FIG. 2. For example, FIG. 6 is a schematic cross-sectional view of a line II-II in FIG. 5B. Each layer in the cross-section of FIG. 6 corresponds to a layer of FIG. 2, so the layer marked with the same reference numeral in the two drawings represent the same layer. Referring to FIG. 5A, FIG. 5B, and FIG. 6, in the embodiment, the first transistor T1B includes a gate G1B, a source S1B, a drain D1B, and a semiconductor layer C1B, wherein the first branch CP1 is connected to the gate G1B, and the first data line DL1B is connected to the source S1B. Similarly, the second transistor T2B includes a gate G2B, a source S2B, a drain D2B, and a semiconductor layer C2B, wherein the second branch CP2 is connected to the gate G2B, and the second data line DL2B is connected to the source S2B.

In the embodiment, the first data line DL1B is connected to one of the source SIB and the drain DIB of the first transistor T1B (for example, the source S1B), and the second data line DL2B is connected to one of the source S2B and the drain D2B of the second transistor T2B (for example, the source S2B). At the same time, the signal line BSB may be electrically connected to the gate G1B and may also be electrically connected to the gate G2B. The first transistor T1B and the second transistor T2B are adjacent in the second direction D2, and the signal line BSB may electrically connect the gate G1B and the gate G2B through a single common signal line SLB, which can reduce the number of lines of the common signal line SLB in the driving circuit 300B to reduce the circuit layout density, thereby reducing parasitic capacitance of the common signal line SLB to achieve the ideal signal transmission effect.

In FIG. 5A, FIG. 5B, and FIG. 6, the gate G1B of the first transistor T1B and the gate G2B of the second transistor T2B are manufactured by, for example, adopting the conductive layer M1 in FIG. 2 wherein the conductive layer M1 is disposed on the insulation layer 12 and is covered by the insulation layer 13. The source SIB and the drain DIB of the first transistor T1B and the source S2B and the drain D2B of the second transistor T2B are manufactured by, for example, adopting the conductive layer M2 in FIG. 2, wherein the conductive layer M2 is disposed on the insulation layer 13 and is covered by the insulation layer 14. In addition, the driving circuit 300B applied to the electronic device 100 also includes multiple vertical signal lines, such as a vertical signal line TL1B and a vertical signal line TL2B. The vertical signal line TL1B and the vertical signal line TL2B are multiple circuits disposed in the peripheral area 102 of the electronic device 100 and extending along the first direction D1. The vertical signal line TL1B and the vertical signal line TL2B may be used to transmit signals. The vertical signal line TL1B is, for example, manufactured by the conductive layer M3 of FIG. 2 and is disposed between the insulation layer 14 and the insulation layer 15. The vertical signal line TL2B is, for example, manufactured by the conductive layer M4 and the conductive layer ITO3 of FIG. 2 and is disposed on the insulation layer 18.

In some embodiments, the vertical signal line TL1B may partially overlap with the common signal line SLB, but the vertical signal line TL1B and the common signal line SLB are different layers, and at least the insulation layer 13 and the insulation layer 14 are sandwiched between the two. Therefore, parasitic capacitance caused by the vertical signal line TL1B to the common signal line SLB is not significant and cannot easily cause an excessive load on the common signal line SLB. In addition, the vertical signal line TL2B partially overlaps with the gate G1B and the first data line DL1B, but the gate G1B, the first data line DL1B, and the vertical signal line TL2B are different layers. Therefore, parasitic capacitance caused by the vertical signal line TL2B to the gate G1B is not significant and cannot easily cause an excessive load on the gate G1B. At the same time, the first data line DL1B also does not generate a significant load due to overlapping with the vertical signal line TL2B. In other embodiments, the vertical signal line TL1B and the vertical signal line TL2B may be manufactured by at least one layer of the conductive layers M3, M4, and ITO1 to ITO3 in FIG. 2.

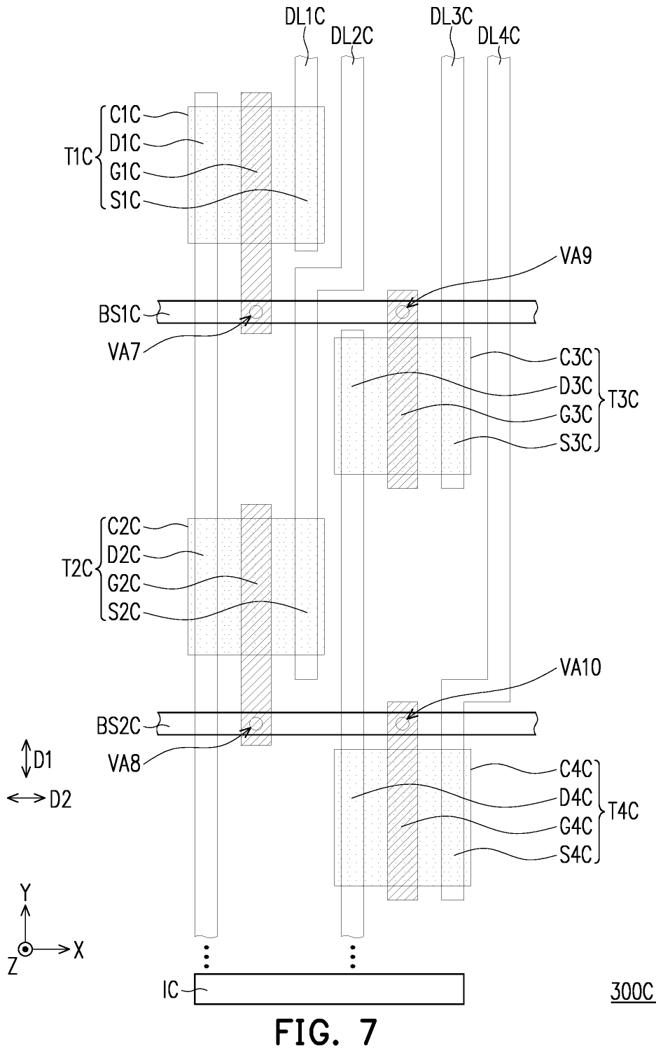

FIG. 7 is a schematic view of a driving circuit of an electronic device according to an embodiment of the disclosure. A driving circuit 300C of FIG. 7 may be applied to the electronic device 100 of FIG. 1 and may be specifically used as a possible implementation of the driving circuit area 102A in the electronic device 100. Therefore, it can be understood that the driving circuit 300C of FIG. 7 is disposed on the substrate 110 of FIG. 1 and is located in the peripheral area 102. Please refer to FIG. 1 and FIG. 7 at the same time. The electronic device 100 having the driving circuit 300C includes multiple data lines DL1C to DL4C and the driving circuit 300C. The data lines DL1C to DL4C extend along the first direction D1. The driving circuit 300C is disposed in the peripheral area 102 (shown in FIG. 1) and includes multiple transistors TIC to T4C, a first signal line BS1C, and a second signal line BS2C. The transistors TIC to T4C are electrically connected to the data lines DL1C to DL4C. Each of the transistors TIC to T4C includes a gate (G1C to G4C). The first signal line BS1C extends along the second direction D2. The first direction D1 is different from the second direction D2, wherein the first direction D1 is, for example, parallel to the Y-axis, and the second direction D2 is, for example, parallel to the X-axis. The first signal line BS1C is electrically connected to the gates G1C and G3C of at least one of the transistors TIC to T4C (for example, the transistor TIC and the transistor T3C). The second signal line BS2C is adjacent to the first signal line BS1C and extends along the second direction D2. The second signal line BS2C is electrically connected to the gates (for example, the gate G2C and the gate G4C) of at least another one of the transistors TIC to T4C (for example, the transistor T2C and the transistor T4C). At least part of the transistors TIC to T4C are disposed between the first signal line BS1C and the second signal line BS2C.

In the embodiment, the second signal line BS2C and the first signal line BS1C being adjacent may be understood as there is no other circuit extending along the second direction D2 and transmitting the same signal between the second signal line BS2C and the first signal line BS1C, so the second signal Line BS2C and the first signal line BS1C may be regarded as adjacent circuits. For example, in some embodiments, the second signal line BS2C and the first signal line BS1C are used to transmit the gate signals, and there is no other circuit for transmitting the gate signal and extending along the second direction D2 between the second signal line BS2C and the first signal line BS1C. In addition, the transistor T2C and the transistor T3C among the transistors TIC to T4C are disposed between the first signal line BS1C and the second signal line BS2C.

In FIG. 7, the transistor TIC includes the gate G1C, a source SIC, a drain D1C, and a semiconductor layer C1C, the transistor T2C includes the gate G2C, a source S2C, a drain D2C, and a semiconductor layer C2C, the transistor T3C includes the gate G3C, a source S3C, a drain D3C, and a semiconductor layer C3C, and the transistor T4C includes the gate G4C, a source S4C, a drain D4C, and a semiconductor layer C4C. The source SIC of the transistor TIC is, for example, connected to the data line DL1C, the source S2C of the transistor T2C is, for example, connected to the data line DL2C, the source S3C of the transistor T3C is, for example, connected to the data line DL3C, and the source S4C of the transistor T4C is, for example, connected to the data line DL4C. The transistors TIC to T4C are arranged in at least two columns. For example, the transistor TIC is the first row, the transistor T2C is the second row, the transistor T3C is the third row, and the transistor T4C is the fourth row.

The transistor TIC and the transistor T3C are located on two opposite sides of the first signal line BS1C, and the gate G1C of the transistor TIC and the gate G3C of the transistor T3C are respectively connected to the first signal line BS1C through a conductive via VA7 and a conductive via VA9. The transistor T2C and the transistor T4C are located on two opposite sides of the second signal line BS2C, and the gate G2C of the transistor T2C and the gate G4C of the transistor T4C are respectively connected to the second signal line BS2C through a conductive via VA8 and a conductive via VA10. The drain D1C of the transistor TIC and the drain D2C of the transistor T2C may be connected to each other, and the drain D3C of the transistor T3C and the drain D4C of the transistor T4C may be connected to each other, thereby implementing the required circuit, such as a multiplexer and a gate driving circuit, but not limited thereto.

In the embodiment, the transistor T2C and the transistor T3C are disposed between the adjacent first signal line BS1C and second signal line BS2C, so the distance between the first signal line BS1C and the second signal line BS2C is increased to reduce mutually generated parasitic capacitance between the two, which can help to reduce the load of the first signal line BS1C and the second signal line BS2C, so as to maintain the signal transmission quality of the first signal line BS1C and the second signal line BS2C.

In some embodiments, the driving circuit 300C further includes an integrated circuit IC, and the integrated circuit IC is electrically connected to the transistors TIC to T4C. The integrated circuit IC may be used as a driving signal source and a power supply. In addition, as shown in FIG. 1, the electronic device 100 further includes the display area 104 and the test circuit area 102B. When applied to the electronic device of FIG. 1, the test signal connected to one of the source and the drain of the transistor in the test circuit area 102B may be provided by other signal sources instead of the integrated circuit IC.

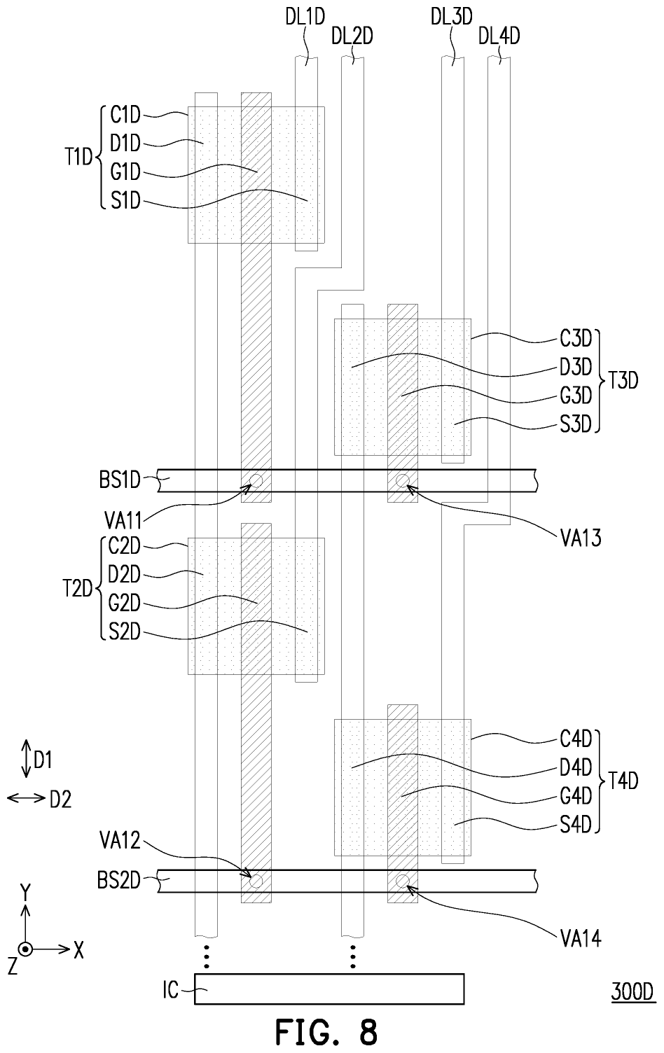

FIG. 8 is a schematic view of a driving circuit of an electronic device according to an embodiment of the disclosure. A driving circuit 300D of FIG. 8 may be applied to the electronic device 100 of FIG. 1 and may be specifically used as a possible implementation of the driving circuit area 102A in the electronic device 100. Therefore, it can be understood that the driving circuit 300D of FIG. 8 is disposed on the substrate 110 of FIG. 1 and is located in the peripheral area 102. Please refer to FIG. 1 and FIG. 8 at the same time. The electronic device 100 may include multiple data lines DL1D to DL4D and the driving circuit 300D. The data lines DL1D to DL4D extend along the first direction D1. The driving circuit 300D is disposed in the peripheral area 102 (shown in FIG. 1) and includes multiple transistors T1D to T4D, a first signal line BS1D, and a second signal line BS2D. The transistors T1D to T4D are electrically connected to the data lines DL1D to DL4D. Each of the transistors T1D to T4D includes a gate (G1D to G4D). The first signal line BS1D extends along the second direction D2. The first direction D1 is different from the second direction D2, wherein the first direction D1 is, for example, parallel to the Y-axis, and the second direction D2 is, for example, parallel to the X-axis. The first signal line BS1D is electrically connected to the gates G1D and G3D of at least one of the transistors T1D to T4D (for example, the transistor T1D and the transistor T3D). The second signal line BS2D is adjacent to the first signal line BS1D and extends along the second direction D2. The second signal line BS2D is electrically connected to the gates (for example, the gate G2D and the gate G4D) of at least another one of the transistors T1D to T4D (for example, the transistor T2D and the transistor T4D). At least part of the transistors T1D to T4D (for example, the transistor T2D and the transistor T4D) are disposed between the first signal line BS1D and the second signal line BS2D.

In the embodiment, the transistors T1D to T4D are arranged in at least two columns. For example, the transistor T1D and the transistor T2D are arranged in the same column, and the transistor T3D and the transistor T4D are arranged in the same column. The driving circuit 300D further includes the integrated circuit IC, and the integrated circuit IC is electrically connected to the transistors T1D to T4D. In FIG. 8, the transistor T1D includes the gate G1D, a source SID, a drain DID, and a semiconductor layer CID, the transistor T2D includes the gate G2D, a source S2D, a drain D2D, and a semiconductor layer C2D, the transistor T3D includes the gate G3D, a source S3D, a drain D3D, and a semiconductor layer C3D, and the transistor T4D includes the gate G4D, a source S4D, a drain D4D, and a semiconductor layer C4D. The source SID of the transistor T1D is, for example, connected to the data line DL1D, the source S2D of the transistor T2D is, for example, connected to the data line DL2D, the source S3D of the transistor T3D is, for example, connected to the data line DL3D, and the source S4D of the transistor T4D is, for example, connected to the data line DL4D. The gate G1D of the transistor T1D and the gate G3D of the transistor T3D are respectively connected to the first signal line BS1D through a conductive via VA11 and a conductive via VA13, and the gate G2D of the transistor T2D and the gate G4D of the transistor T4D are respectively connected to the second signal line BS2D through a conductive via VA12 and a conductive via VA14. The drain DID of the transistor T1D and the drain D2D of the transistor T2D may be connected to each other, and the drain D3D of the transistor T3D and the drain D4D of the transistor T4D may be connected to each other.

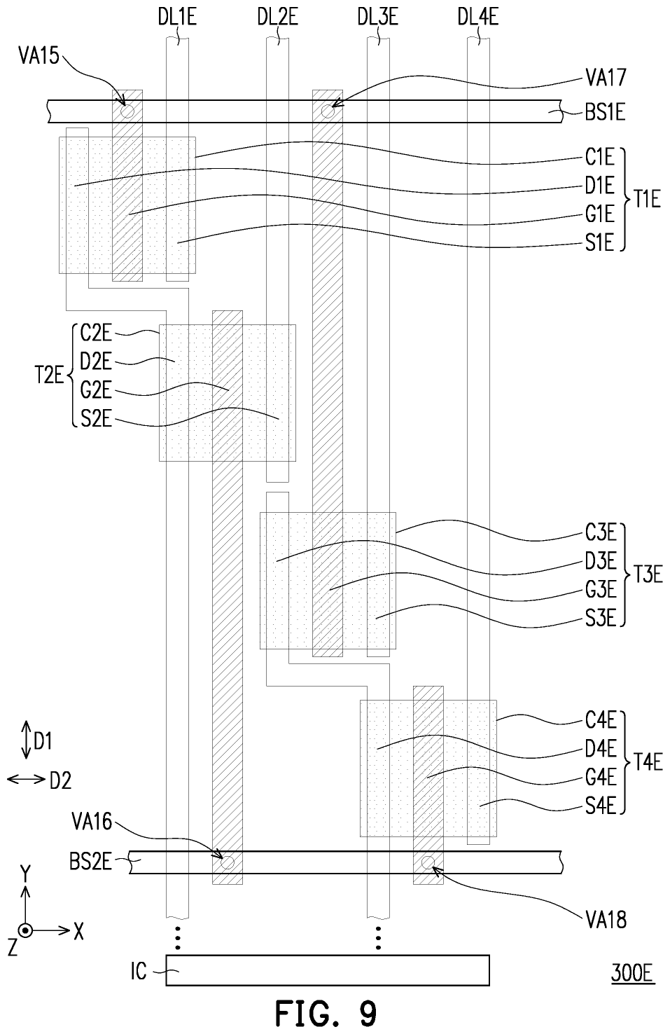

FIG. 9 is a schematic view of a driving circuit of an electronic device according to an embodiment of the disclosure. A driving circuit 300E of FIG. 9 may be applied to the electronic device 100 of FIG. 1 and may be specifically used as a possible implementation of the driving circuit area 102A in the electronic device 100. Therefore, it can be understood that the driving circuit 300E of FIG. 9 is disposed on the substrate 110 of FIG. 1 and is located in the peripheral area 102. Please refer to FIG. 1 and FIG. 9 at the same time. The electronic device 100 may include multiple data lines DL1E to DL4E and the driving circuit 300E. The data lines DL1E to DL4E extend along the first direction D1. The driving circuit 300E is disposed in the peripheral area 102 (shown in FIG. 1) and includes multiple transistors T1E to T4E, a first signal line BS1E, and a second signal line BS2E. The transistors T1E to T4E are electrically connected to the data lines DL1E to DL4E. Each of the transistors T1E to T4E includes a gate (G1E to G4E). The first signal line BS1E extends along the second direction D2. The first direction D1 is different from the second direction D2, wherein the first direction D1 is, for example, parallel to the Y-axis, and the second direction D2 is, for example, parallel to the X-axis. The first signal line BS1E is electrically connected to the gates G1E and G3E of at least one of the transistors T1E to T4E (for example, the transistor T1E and the transistor T3E). The second signal line BS2E is adjacent to the first signal line BS1E and extends along the second direction D2. The second signal line BS2E is electrically connected to the gates (for example, the gate G2E and the gate G4E) of at least another one of the transistors T1E to T4E (for example, the transistor T2E and the transistor T4E). At least part of the transistors T1E to T4E are disposed between the first signal line BS1E and the second signal line BS2E. In addition, as shown in FIG. 1, the electronic device 100 further includes the display area 104. The display area 104 is adjacent to the peripheral area 102. In some embodiments, the first signal line BS1E may be disposed between the transistors T1E to T4E and the display area 104. In some embodiments, the driving circuit 300E further includes the integrated circuit IC, and the integrated circuit IC is electrically connected to the transistors T1E to T4E.

In FIG. 9, the transistor T1E includes the gate G1E, a source S1E, a drain DIE, and a semiconductor layer CIE, the transistor T2E includes the gate G2E, a source S2E, a drain D2E, and a semiconductor layer C2E, the transistor T3E includes the gate G3E, a source S3E, a drain D3E, and a semiconductor layer C3E, and the transistor T4E includes the gate G4E, a source S4E, a drain D4E, and a semiconductor layer C4E. The source S1E of the transistor T1E is, for example, connected to the data line DL1E, the source S2E of the transistor T2E is, for example, connected to the data line DL2E, the source S3E of the transistor T3E is, for example, connected to the data line DL3E, and the source S4E of the transistor T4E is, for example connected to the data line DL4E. The transistors T1E to T4E are arranged in at least two columns. For example, the transistors T1E to T4E are respectively arranged in different columns.

In the embodiment, the transistors T1E to T4E are all disposed between the first signal line BS1E and the second signal line BS2E. The drain DIE of the transistor T1E and the drain D2E of the transistor T2E may be connected to each other, and the drain D3E of the transistor T3E and the drain D4E of the transistor T4E may be connected to each other, so as to implement the required circuit. The gate G1E of the transistor T1E and the gate G3E of the transistor T3E are respectively connected to the first signal line BS1E through a conductive via VA15 and a conductive via VA17. The gate G2E of the transistor T2E and the gate G4E of the transistor T4E are respectively connected to the second signal line BS2E through a conductive via VA16 and a conductive via VA18. In this way, the first signal line BS1E and the second signal line BS2E controlling the two adjacent transistors (for example, the transistor T1E and the transistor T2E) are separated by the transistors T1E to T4E, which can help to reduce parasitic capacitance between the first signal line BS1E and the second signal line BS2E to maintain the ideal signal transmission quality.

In the disclosure, the source and the drain described in the drawings refer to two electrodes connected to different regions of the semiconductor layer and located on two sides of the gate, wherein one of the two electrodes is named the source and the other one is named the drain. Therefore, the source and the drain described in the above embodiments may be replaced with each other and are not limited by the above words and expressions. In addition, although the driving circuit described in the above embodiments is disposed in the peripheral area 102 of the electronic device 100 for illustration, the driving circuit described in the above embodiments may actually be electrically connected to the pixel structure, the sensing element, etc. located in the display area 104. In addition, the driving circuit described in the above embodiments may be manufactured by adopting the same film layer as the pixel structure in the display area 104, so the driving circuit and the pixel structure are both disposed on the substrate 110 (may refer to FIG. 2, FIG. 4, or FIG. 6).

In summary, the electronic device of the embodiments of the disclosure has the panel type, and multiple transistors, multiple data lines, and multiple signal lines are disposed in the peripheral area. The transistors, the data lines, and the signal lines are densely configured to meet the requirement of high resolution. In addition, the adjacently disposed signal lines may be different layers, which can help to reduce parasitic capacitance between the adjacent signal lines to reduce the load of the individual signal lines, so as to optimize the signal transmission effect of the signal lines. For example, the charging efficiency of the transistors can thus be improved. In addition, the adjacent transistors may share the signal lines through the connection portion having the branches, which can reduce the number of signal lines, so that the layout of the signal lines is more flexible and may be configured at a relatively loose density, thereby effectively reducing parasitic capacitance between the adjacent signal lines. In some embodiments, the transistors may be disposed between the adjacent signal lines to increase the distance between the signal lines, so that parasitic capacitance between the adjacent signal lines can also be effectively reduced. The electronic device of the embodiments of the disclosure can maintain the ideal signal transmission effect when applied to a high-resolution product, thereby providing good display and/or touch effects.

Finally, it should be noted that the above embodiments are only used to illustrate, but not to limit, the technical solutions of the disclosure. Although the disclosure has been described in detail with reference to the above embodiments, persons skilled in the art should understand that the technical solutions described in the above embodiments may still be modified or some or all of the technical features thereof may be equivalently replaced. However, the modifications or replacements do not cause the essence of the corresponding technical solutions to deviate from the scope of the technical solutions of the embodiments of the disclosure.

What is claimed is:

1. An electronic device, having a peripheral area and comprising:
a first data line and a second data line, extending along a first direction;
a first transistor and a second transistor, adjacently disposed in the peripheral area and respectively electrically connected to the first data line and the second data line;
a first signal line and a second signal line, extending along the first direction and at least partially disposed between the first transistor and the second transistor,
wherein the first signal line and the second signal line are different layers.

2. The electronic device according to claim 1, further comprising an insulation layer disposed between the first signal line and the second signal line.

3. The electronic device according to claim 1, wherein the first signal line is a first conductive layer, the second signal line is a second conductive layer, and a separation distance between the first conductive layer and the second conductive layer in a thickness direction is greater than or equal to 0.5 microns.

4. The electronic device according to claim 1, wherein a minimum separation distance between the first signal line and the second signal line is 0.4 microns.

5. The electronic device according to claim 1, further comprising a display area adjacent to the peripheral area and a pixel structure disposed in the display area.

6. The electronic device according to claim 5, wherein the pixel structure is implemented by a multi-layer conductive layer, and the first signal line and the second signal line are manufactured by two different layers of the multi-layer conductive layer.

7. The electronic device according to claim 1, wherein the first transistor and the second transistor are arranged in a second direction, and there is no other transistor between the first transistor and the second transistor.

8. The electronic device according to claim 1, wherein contour orthographic projections of the first signal line and the second signal line on a plane of an X-axis and a Y-axis are substantially aligned with each other.

9. An electronic device, having a peripheral area and comprising:
a first data line and a second data line, extending along a first direction;
a first transistor and a second transistor, disposed in the peripheral area and respectively electrically connected to the first data line and the second data line;
a signal line, disposed in the peripheral area and extending along a second direction, wherein the first direction is different from the second direction,
a connection portion, electrically connected to the signal line and comprising a first branch and a second branch, wherein the first branch electrically connects the first transistor and the signal line, and the second branch electrically connects the second transistor and the signal line.

10. The electronic device according to claim 9, wherein the first branch and the second branch are symmetrical.

11. The electronic device according to claim 9, wherein the first transistor and the second transistor respectively comprise a gate, a source, and a drain, and the signal line is electrically connected to the gate.

12. The electronic device according to claim 11, wherein the first data line is connected to one of the source and the drain of the first transistor, and the second data line is connected to one of the source and the drain of the second transistor.

13. The electronic device according to claim 9, further comprising a common signal line extending along the first direction and connecting the signal line and the connection portion.

14. The electronic device according to claim 13, further comprising a vertical signal line extending along the first direction and partially overlapping with the common signal line.

15. An electronic device, having a peripheral area and comprising:
a plurality of data lines extending, along a first direction; and
a driving circuit, disposed in the peripheral area and comprising:
a plurality of transistors, electrically connected to the data lines, wherein each of the transistors comprises a gate;
a first signal line, extending along a second direction and electrically connected to the gate of at least one of the transistors, wherein the first direction is different from the second direction; and
a second signal line, adjacent to the first signal line, extending along the second direction, and electrically connected to the gate of at least another one of the transistors;
wherein at least part of the transistors are disposed between the first signal line and the second signal line.

16. The electronic device according to claim 15, wherein the transistors are arranged in at least two columns.

17. The electronic device according to claim 15, wherein the driving circuit further comprises an integrated circuit electrically connected to the transistors.

18. The electronic device according to claim 15, further comprising a display area adjacent to the peripheral area, wherein the first signal line is disposed between the transistors and the display area.

19. The electronic device according to claim 15, further comprising a display area and a test circuit area, wherein the driving circuit is disposed between the display area and the test circuit area.

20. The electronic device according to claim 15, further comprising a pixel structure disposed in the display area.
